(19) United States
(12) Patent Application Publication
(10) Pub. No.: US 2013/0127309 A1
(43) Pub. Date: May 23, 2013

(54) PROTECTIVE CASES AND METHODS OF MAKING

(71) Applicant: G-Form, LLC, Providence, RI (US)

(72) Inventors: Daniel M. Wyner, North Scituate, RI (US); Stephanie Thorn, Chepachet, RI (US); Richard L. Garrard, Newport, RI (US); Maria E. Macrina, Providence, RI (US); James E. Gaudet, Blackstone, MA (US); Mark Ross Hampton, Waitakere (NZ)

(73) Assignee: G-Form, LLC, Providence, RI (US)

(21) Appl. No.: 13/673,654

(22) Filed: Nov. 9, 2012

Related U.S. Application Data
(60) Provisional application No. 61/674,380, filed on Jul. 22, 2012.
(60) Provisional application No. 61/674,844, filed on Jul. 23, 2012.
(60) Provisional application No. 61/676,305, filed on Jul. 26, 2012.

(30) Foreign Application Priority Data
Nov. 9, 2011 (NZ) 596294

(51) Int. Cl. H05K 5/02

(52) U.S. Cl. CPC H05K 5/0217
USPC 312/223.1

(57) ABSTRACT

Disclosed herein are protective inserts for sensitive devices, including devices with screen interfaces, which cases provide protection from front, back and edge impacts.

### CROSS-REFERENCE TO RELATED APPLICATIONS

The present application claims foreign priority under 35 U.S.C. §119 to commonly owned and co-pending New Zealand Provisional Application No. 596294, which was filed on Nov. 9, 2011; and to commonly owned and co-pending U.S. Provisional Application No. 61/674,380, which was filed on Jul. 22, 2012; U.S. Provisional Application No. 61/674,844, which was filed on Jul. 23, 2012; and U.S. Provisional Application No. 61/676,305, which was filed on Jul. 26, 2012. The subject matter of each of the foregoing applications is incorporated herein by reference in its entirety.

### TECHNICAL FIELD

The present disclosure relates to protective cases and, in particular, to impact absorbing cases.

### BACKGROUND

Mobile phones and other similar forms of portable media devices commonly include cameras. However, the cameras provided in these devices do not incorporate high-quality optical elements and are not specifically adapted for photographic applications.

Many manufacturers have attempted to solve the foregoing problem. Some manufacturers make cell phone camera kits that include lens-attaching cases. Such cases may include integral or attachable lens mounts that align with the built-in lens of the cell phone, to which separate lenses can be releasably attached. However, if a user already has a protective case on their phone, it is necessary to remove the user's protective case and replace it with the lens-attaching case. During the removal and replacement process, the cell phone is vulnerable to damage and, even with the lens-attaching case in place, the replacement case may not be suitable for everyday use as a protective cover because it provides inferior protection, or the case may be heavy and bulky.

Other attempts involve lenses that detachably connect directly to a cell phone over the built-in lens of the camera, rather than to a cell phone case. Such attempts involve a variety of fastening means, such as adhesives, magnets, and the like. It has been suggested that magnets interfere with the proper function of the phone, as well as can prevent the use of a protective cover. The use of an adhesive eliminates the necessity for affixing a permanent magnet to the cell phone, but can be less reliable.

Still other attempts involve case sections or sleeves with integral lenses, which can be removably attached directly to a cell phone. These types of partial cases avoid the use of adhesives or permanent magnets, but also prevent or interfere with the use of a protective case while using the lens, leaving the cell phone vulnerable to damage.

Still others have integrated lens turrets into a sleeve-style cell phone case. These types of cases are bulky.

Still other manufacturers make cell phone cases with an integral, slideable lens that moves from a first position adjacent to the built-in lens to a second position disposed over the built-in lens. This type of case only allows the use of a single type of alternate lens. Therefore, a separate case is required for each type of lens that a user would like to use.

All of the foregoing cases and devices may suffer from problems because they may interfere with the proper function of the cell phone, they may leave the cell phone vulnerable to damage during the replacement process, and they may require additional items to carry around. These and other reasons minimize the use of media device cameras for photographic applications.

### SUMMARY

The present disclosure is directed, in one embodiment, to a protective case for a media device with a built-in camera lens, comprising a protective element comprising a base and a sidewall extending upwardly from the base to define an enclosure adapted to receive the media device, a housing element comprising a base and a sidewall extending upwardly from the base to define an enclosure adapted to receive the protective element, and a cover removably connected to the base, and a lens window disposed in the base. When the media device is disposed in the protective case, the built-in camera lens is coaxially aligned with the lens window, and the protective element is sufficiently compressed against the interior of the enclosure to maintain the built-in lens in coaxial alignment with the lens window.

### BRIEF DESCRIPTION OF THE DRAWINGS

The foregoing and other features and advantages will be apparent from the following more particular description of exemplary embodiments of the disclosure, as illustrated in the accompanying drawings, in which like reference characters refer to the same parts throughout the different views. The drawings are not necessarily to scale, emphasis instead being placed upon illustrating the principles of the disclosure. Referring now to the figures, which are exemplary embodiments, and wherein like elements are numbered alike

FIG. 1 is a rear perspective view of one embodiment of a housing system for a media device, according to the present disclosure, which includes a housing element and a protective element (shown through a cut-away in the housing element);

FIG. 2 is a front perspective view of the housing element of the housing system shown in FIG. 1;

FIG. 3 is a rear perspective view of the housing element shown in FIG. 2;

FIG. 4 is a side view of the housing element shown in FIG. 1, in an closed position;

FIG. 5 is a side view of the housing element shown in FIG. 1, in an open position;

FIG. 6 is a rear perspective view of the protective element of the housing system shown in FIG. 1;

FIG. 7 is a cross-sectional view of the protective element shown in FIG. 5, through line 7-7;

FIG. 8 is a front perspective view of the housing system shown in FIG. 1, with a media device disposed therein;

FIG. 9 is a cross-sectional view of the housing system shown in FIG. 8, showing media device enclosed in the protective element, and the protective element enclosed by the housing element;

FIG. 10 is a side view of another embodiment of the housing system shown in FIG. 1, with a magnetic grommet disposed on the lens window support member, and a corresponding detachable enhancement lens;

FIG. 11 is a side view of another embodiment of the housing system shown in FIG. 1, with a magnetic grommet disposed on the lens window support member, and a corresponding detachable 90 degree enhancement lens;

FIG. 12 is a side view of another embodiment of the housing system shown in FIG. 1, with a recessed lens window support member, and a corresponding detachable enhancement lens;

FIG. 13 is a perspective view of another embodiment of a protective case according to the present disclosure;

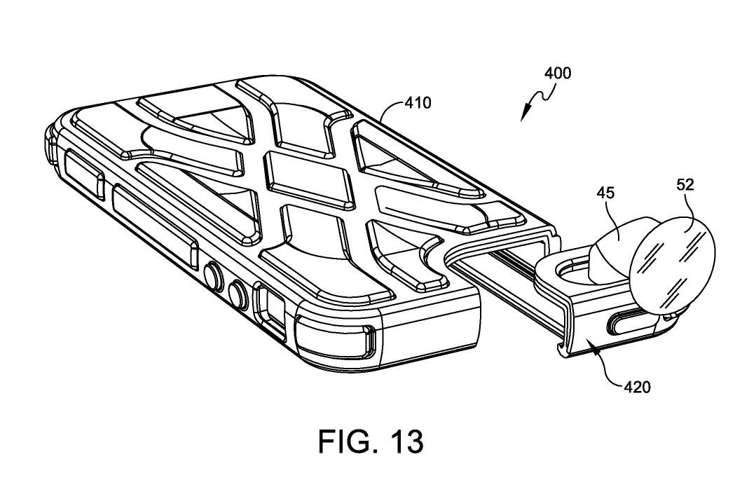

FIG. 14 is a perspective view of another embodiment of a protective case according to the present disclosure;

FIG. 15 is a perspective view of a mounting system according to the present disclosure, that includes a mounting sled and a protective case according to FIG. 13;

FIG. 16 is a perspective view of the mounting system of FIG. 15, mounted to the underside of a surface;

FIG. 17 is a perspective view of an alternative mounting system according to the present disclosure, that includes a mounting sled and a protective case according to FIG. 13, showing the mounting sled mounted to the underside of a surface;

FIG. 18 is an exploded view of a section of the mounting system shown in FIG. 17; and

FIG. 19 is an exploded cross-sectional view of the mounting system shown in FIG. 18.

### DETAILED DESCRIPTION OF PREFERRED EMBODIMENTS

The present invention relates to a protective housing system that may be adapted to protect a wide range of items of varying shapes, sizes and dimensions. For example, the protected item may be a musical instrument, a wine bottle, a medical instrument, and the like. housing system for use with a broad range of items, such as items for which it may be desirable to provide protection from various conditions, such as impacts, vibration, water, chemicals, and the like.

In one embodiment, the item to be protected 300 is an exemplary media device, and one of many media devices available in the marketplace, for example, a cell phone with still and/or video media device capability. For ease of illustration, the item to be protected 300 will be referred to hereinafter as media device 300.

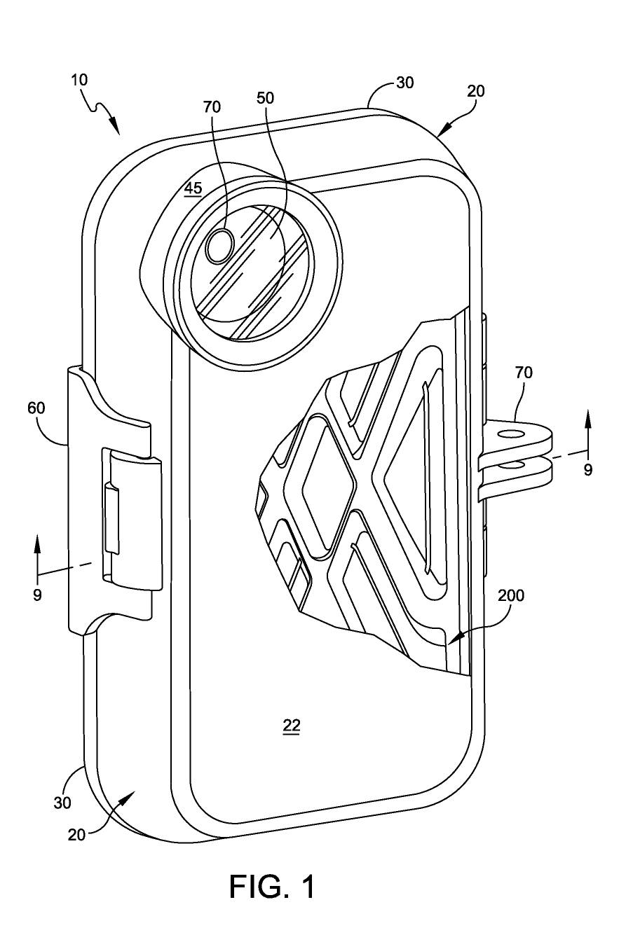

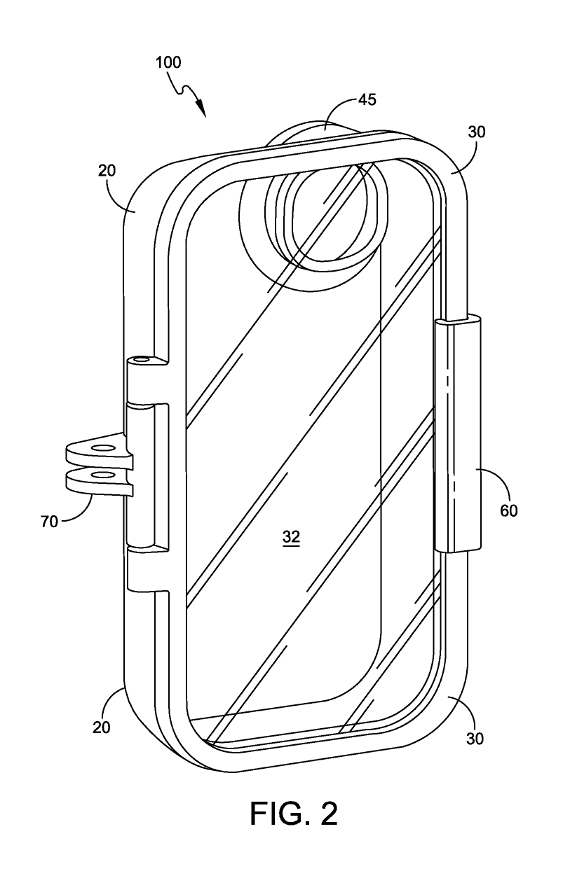

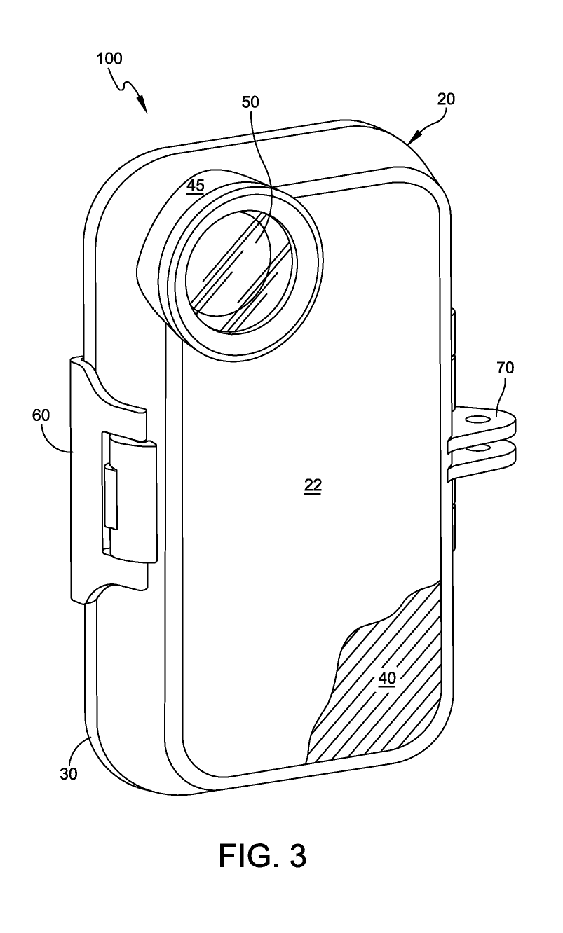

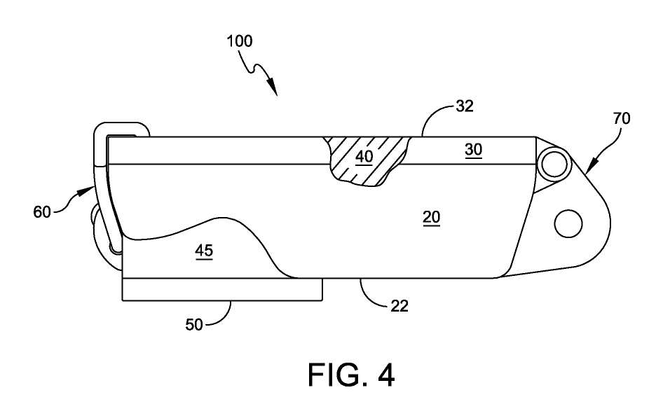

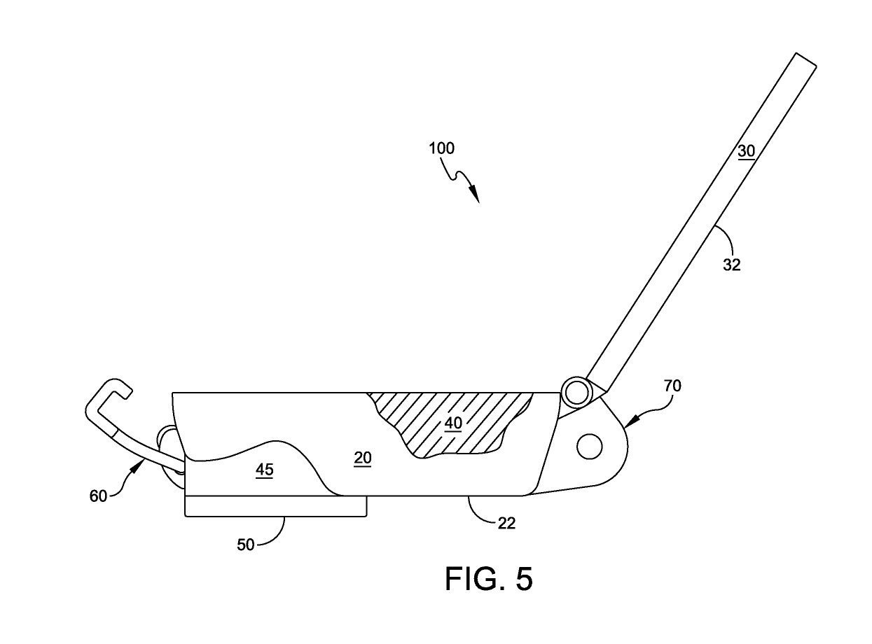

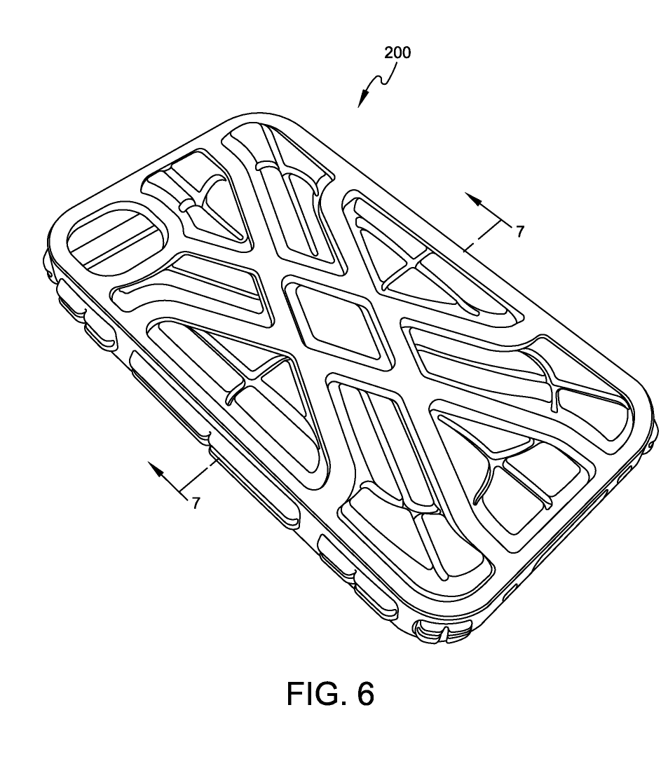

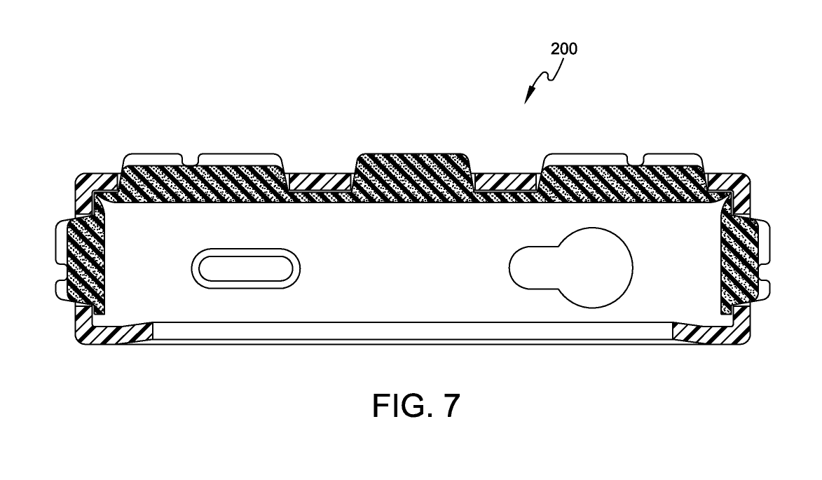

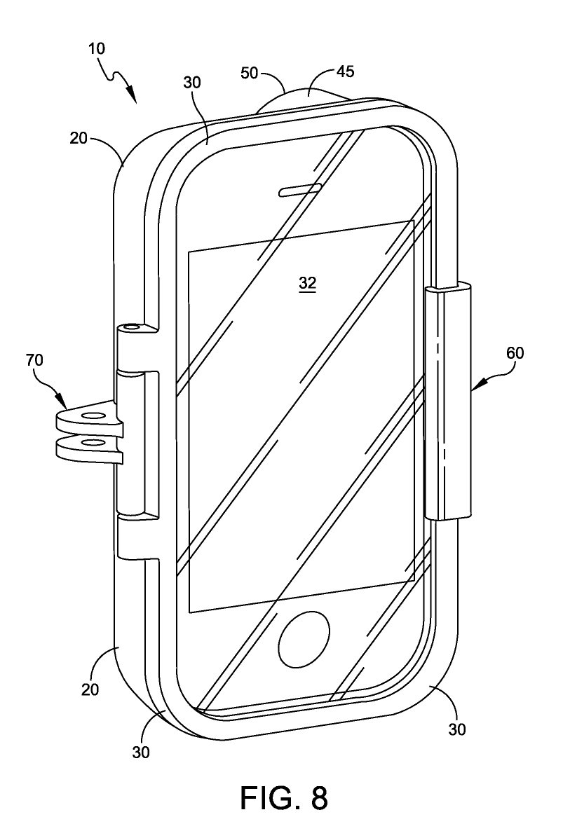

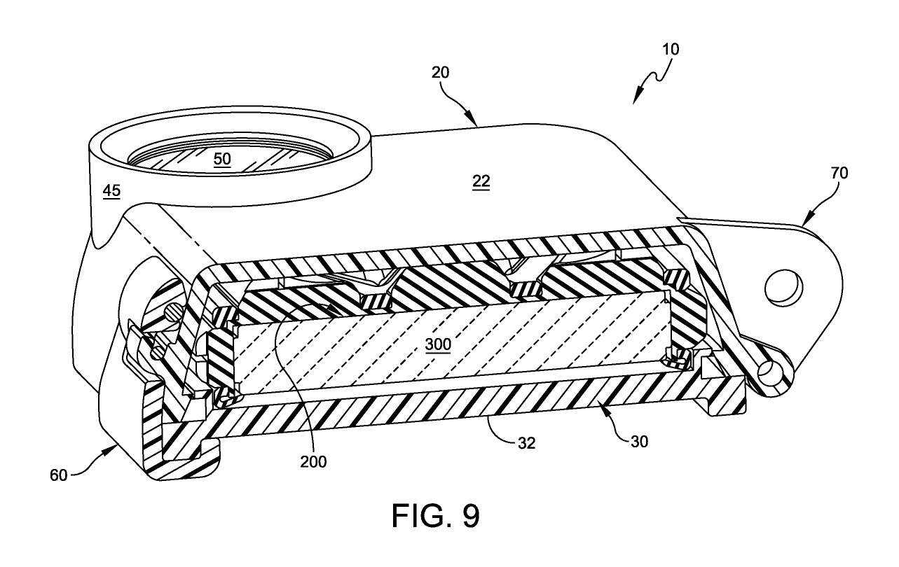

FIGS. 1-9, when taken together, illustrate various views of one embodiment of a protective housing system 10 in accordance with the present disclosure. The housing system 10 comprises a housing element 100 and a protective element 200 that together define a protective enclosure 40 for the media device 300.

The present protective housing system 10 may also be adapted for a wide range of items of varying shapes, sizes and dimensions. For example, the protected item may be a musical instrument, a wine bottle, a medical instrument, and the like. In the present embodiment, the item to be protected 300 is an exemplary media device, and one of many media devices available in the marketplace, for example, a cell phone with still and/or video media device capability. For ease of illustration, the item to be protected 300 will be referred to hereinafter as media device 300.

As shown, housing element 10 comprises a first housing section 20 (for ease of illustration, the first housing section 20 will be referred to hereinafter as “base 20”) and a second housing section 30 (for ease of illustration, the second housing section 30 will be referred to hereinafter as “cover 30”), both of which together are adapted to mate in complementary fashion to form the protective enclosure 40.

The base 20 includes a back face 22 with four sidewalls extending from the back face 22 (i.e. a top side, bottom side, left side, and right side) which together are structured to form the enclosure 40, which is sized and dimensioned to receive the protective element 200 therein.

A support member 45 extends upwardly from the back face 22 and a lens window 50 is disposed parallel to the back face 22, and supported on the support member 45. The support member 45 may be integrally formed with the base 20, or interconnected thereto, permanently or temporarily. Similarly, the lens window 50 may be integrally formed with support member 45, or interconnected thereto, permanently or temporarily. The lens window 50 may be open, such that the enclosure 40 is fluidly connected to the atmosphere outside of the housing element 100, or it may comprise a window element 52 that provides a seal to prevent or minimize fluid communication between the enclosure 40 and the atmosphere outside of the housing element 100.

For example, a seal (e.g., a compressed O-ring) can be disposed between the window element 52 and the support member 45 so as provide a water resistant or waterproof seal therebetween, minimizing or preventing fluid communication between the enclosure 40 and the atmosphere. Alternatively, the window element 52 may be integrally formed with, or permanently fixed to the support member 45.

In the present embodiment, the support member 45 is cylindrical, and is oriented such that the axis of the cylinder is about perpendicular to the cover 30 and/or back face 22. As a result, when a media device 300 is disposed in the enclosure 40, the built-in lens of the media device 300 and the lens window 50 are in coaxial alignment.

The cover 30 detachably couples with the base 20 opposite the back face 22 of the base 20. In use, the base 20 and cover 30 are collectively structured to enclose the protective element 200 within the enclosure 40 when the cover 30 is secured to the base 20 in a closed position.

The housing element 100 may comprise a variety of materials capable of withstanding the conditions in which the housing system 10 may be used. For example, the housing element 100 may comprise a rigid or substantially rigid material such as, but not limited to, plastic, metal, fiberglass, and the like.

In some embodiments, the housing element 10 may be appropriately configured for impact resistance. Examples of suitable materials for impact-resistance include, but are not limited to, impact resistant engineering plastics such as polycarbonate, ABS, acrylic and the like, composites thereof, and combinations thereof.

Any or all of the foregoing materials may comprise additives such as fibers, fillers, colorants and the like, including reinforcing fibers and/or fillers, composites thereof, and combinations thereof.

The wall thickness of the base and cover 20, 30 may vary as needed or desired for the application in which the case is intended for use. In the present embodiment, the wall thickness may be approximately 0.125 inches.

Optionally, the housing element 10 or portions thereof may comprise a transparent material, such that the back face 22 provides a viewing window for visual displays (e.g., menus, picture previews, etc.) on an operational media device 300 disposed in the enclosure 40.

Optionally, the housing element 10 or portions thereof may comprise an optical quality material, such as the back face 22 and lens window 50. For example, the housing element 10 may be formed from polycarbonate, which can be buffed to an optical quality finish in the back face 22 and lens window region 50.

Optionally, the housing element 10 or portions thereof may comprise a scratch-resistant film, coating, and the like, or combinations thereof, disposed on the inner surface thereof, the outer surface thereof, or both the inner and outer surface thereof.

In one embodiment, the protective element 200 comprises a material or structure that is configured and dimensioned to conform to at least a portion of the interior of the housing element 10. The protective element 200 may be formed from a variety of materials that are capable of being compressed sufficiently to securely accommodate the media device 300 therein e.g., such that the device 300 compresses the protective element 200 against the interior surface of the enclosure 40. Suitable materials include, but are not limited to, resiliently deformable impact absorbing and/or vibration dampening materials, and the like. One suitable material is an impact-absorbing material, such as a rate dependent material, particularly impact-absorbing foam materials, one of which is Poron XRD.

In the present embodiment, the protective element 200 is a media device case configured and dimensioned to receive the media device 300 therein. One suitable case is a two-piece media device available from G-Form, LLC, Providence, R.I.

A variety of fastening assemblies or devices may be used to secure the cover 30 to the base 20 including, but not limited to, a button assembly, a buckle assembly, a clip assembly, a hook and loop assembly, a magnet assembly, a ball and catch assembly, and an adhesive assembly, or any other type of fastening assembly or device.

The various parts forming the fastening assembly are configured and arranged to secure the cover 30 to the base 20. In the present embodiment, the housing system 10 comprises a hinged fastener 60 on one side and a releasable fastener 70 on the opposite side, both of which cooperate to allow the cover 30 to move from an open position to a closed position.

When in an open position, the housing system 10 is adapted to receive the protective element 200 into the enclosure 40, and to allow an item 300 to be disposed in the protective element 200, followed by closing the cover 30 and securing it to the base 20 by engaging the releaseable fastener 70. Alternatively, the item 300 first can be disposed in the protective element 200, and the protective element enclosing the item 300 can in turn be disposed in the enclosure 40.

Once disposed in the enclosure 40, the protective element 200 can be compressed sufficiently against the interior sidewalls of the enclosure 40, as in a friction fit, to minimize or prevent movement of the item 300 in the housing system 10.

In one embodiment, the housing system 10 may be appropriately configured for use in various elements. For example, the enclosure 40 may be waterproof to protect the media device 300 from water when used, for example, while surfing or scuba diving, by providing a watertight O-ring seal between the body and cover, and in the lens mount, if releasably attached to the base.

Optionally, in one embodiment, a sealing structure (not illustrated) may be disposed at the perimeter of the base 20 and/or the cover 30, to provide a water resistant or waterproof enclosure 40. For example, the base 20 and the cover 30 may be mated with an intervening sealing structure, such as an O-ring, and held together in the closed position by the fastening mechanism while compressing the intervening sealing structure to form a seal between the base 20 and the cover 30. The sealing structure may be impact-resistant, watertight, or a both. A variety of materials may be used for the sealing structure including, but not limited to, silicone, rubber, TPE, rate dependent materials, foams thereof, composites thereof, and the like, and combinations thereof.

Alternatively, the base and cover may be semi-permanently sealed with the use of RTV, or the like.

In one embodiment, cover 30 may comprise vents (not illustrated) to provide airflow and/or cooling to the media device, in situations where water resistance is not a concern.

The housing system 10 can provide a waterproof and/or impact resistant system with which a user can capture and wirelessly download images and/or video in real-time from the media device 300, as well as wirelessly control operation of the media device. For example, if the housing system 10 is mounted on a bicycle handlebar, with the protective element 200 disposed in the enclosure 40 and the media device 300 disposed in the protective element 200, the user can remotely control the media device contained therein using voice commands via Bluetooth enabled devices, Wi-Fi, and the like.

The housing system 100 is advantageous when using the media device 200 in situations in which it may be susceptible to damage. For example, without the housing 100, the media device may become scratched or otherwise damaged when used during physical activity. Thereafter, the media device 300 is removable from the housing for normal use as a media device.

In use, the camera lens 70 of the media device 300 is substantially aligned with the lens window 50 when the media device 300 is secured in the protective element 200, and in the housing 10. That is, the lens 60 and the lens window 50 are disposed in coaxial alignment.

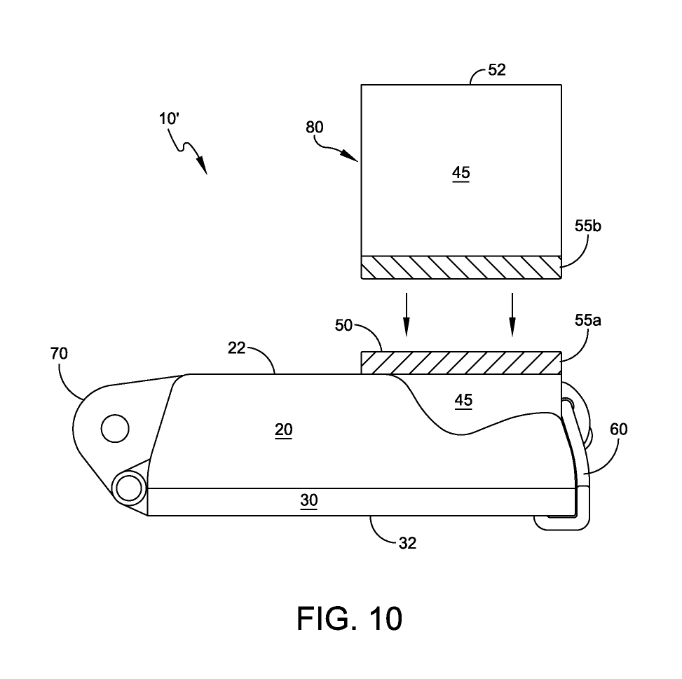

Another aspect of the present disclosure is a housing system with an integral enhancement lens, or that can be used with one or more interchangeable enhancement lenses. FIGS. 10-12 illustrate other embodiments of housing system 10 in accordance with the present disclosure, which have a similar construction as in the previous embodiment, and additionally comprise at least one enhancement lens 60. Examples of suitable enhancement lenses include, but are not limited to, wide-angle, telephoto, fisheye, close-up or macro adapters, and the like. The enhancement lens 60 can be integrally formed with, permanently connected to or removably attachable to the base 20 and/or to the support member 45. The enhancement lens 60 can comprise a variety of removable attachment devices and methods including, but not limited to, magnets, optical lens mounts (such as a C-mount, T-mount, and the like), bayonet mounts, plug-in mounts, side-in mounts, screw-in mounts, and the like.

FIG. 10 shows a housing system 10′ in accordance with the present disclosure, which has a similar construction as in the previous embodiment, and additionally includes at least one detachable enhancement lens 80 with a lens window 52. The lens enhancement is desirably sized and dimensioned to correspond to the dimensions of the support member 45 and/or lens window 50, and can comprise a variety of internally disposed lens elements. In the present embodiment, a circular magnet 55a is attached to the upper edge of the support member 45 (i.e., by gluing, comolding, and the like) such that it is coaxial with the axis of the support member. The enhancement lens 80 is barrel or cylindrically shaped and comprises a corresponding circular magnet 55b disposed at the lower edge to correspond to the circular magnet 55a disposed on the upper end of the support member 45 at lens window 50. Lens 80 is adapted for removable attachment to the lens window 50 at 55a. Optionally, a variety of such enhanced lenses 60 may be adapted for use with the housing 10′, for each of interchangeability.

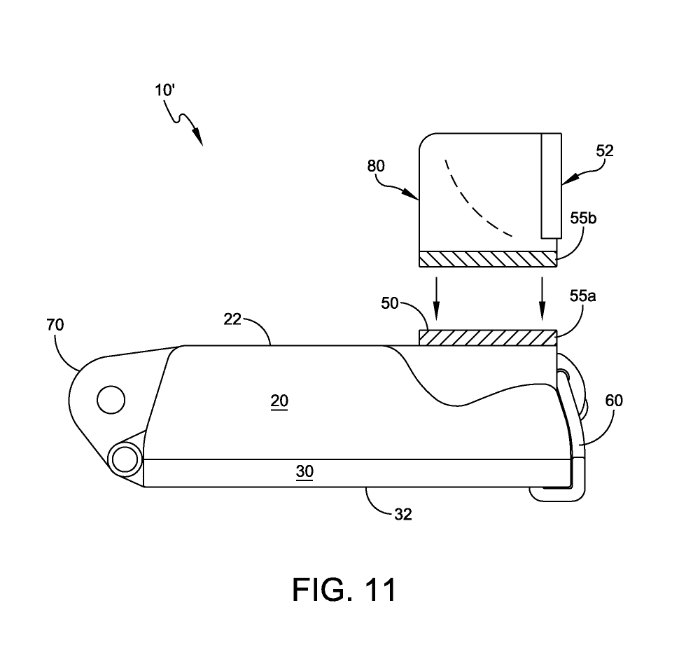

FIG. 11 shows a housing system 10″ in accordance with the present disclosure, which has a similar construction as in the previous embodiment. In the present embodiment, the enhancement lens 80′ comprises a 90 degree lens, which allows a user to change the orientation of the view through the built-in lens of the media device 300. To accommodate the 90 degree lens, the lens window 52 can be disposed perpendicularly to the axis of lens window 50. The enhancement lens 80′ may comprise a prism disposed at an angle of about ninety (90) degrees to the lens window 50, with an intermediate device (not illustrated) adapted to receive the image from the lens window 50 and transmit or reflect the image to the media device lens for processing. Optionally, the enhancement lens 60 may swivel or rotate to change the direction of the camera shot.

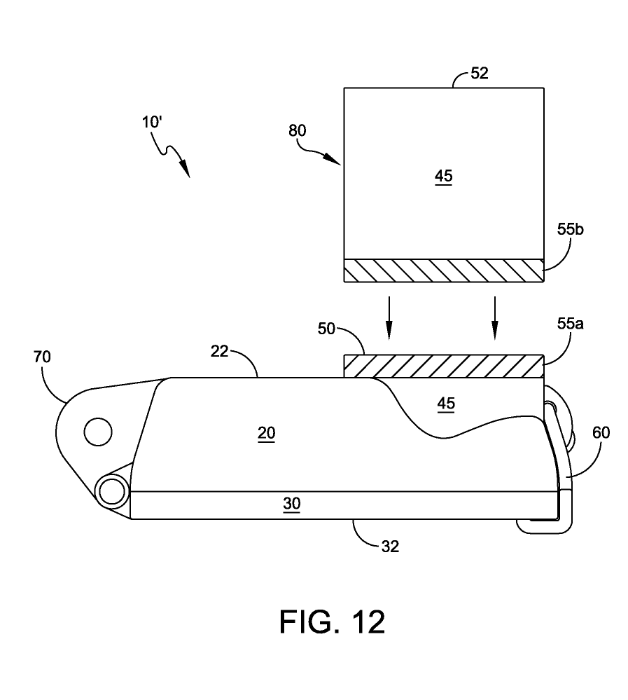

FIG. 12 shows a housing system 10″ in accordance with the present disclosure, which has a similar construction as housing system 10″, and additionally includes a recessed lens window 50, with a magnetic grommet 55a disposed in the recess at the lower edge. Either of enhancement lenses 80, 80′ may be used by insertion into the recessed lens window 50′ and engagement of the magnets 55a,b with each other. As in the previous embodiment, a variety of such lenses may be adapted for use with the housing, for each of interchangeability.

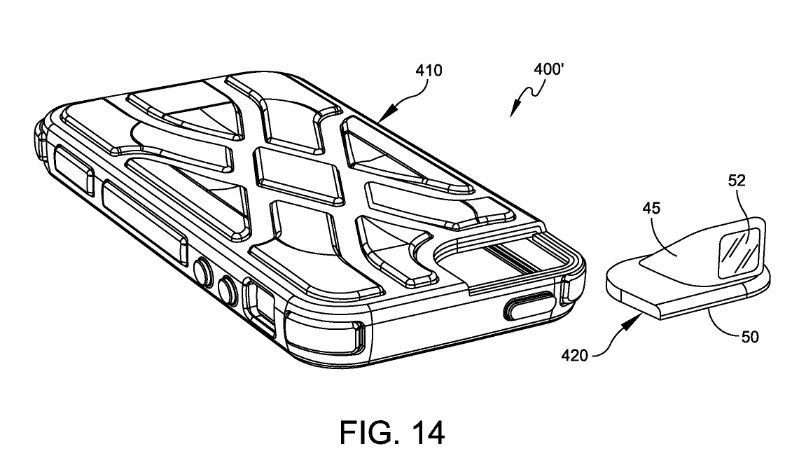

Another aspect of the present disclosure is illustrated in FIG. 14, which shows a protective case 400 for a media device (not illustrated) that comprises a body section 410 and an interchangeable detachable lens section 420, both of which together cover the media device, other than the screen region (not illustrated). As in previous embodiments, the detachable lens section 420 may include an additional lens enhancement 80, such as a 90 degree lens with lens window 52, as shown in the present embodiment.

The body section 410 covers a relatively large region of the cell phone, and the detachable lens section 420 covers a relatively smaller region of the cell phone, in comparison to the body section 410. The detachable lens sections 420 can comprise an integral or detachable enhancement lens 80 that is supported on the lens section 420.

To maximize the protective features of the case 400, the lens section 420 is designed to cover the built-in lens of the camera and the surrounding adjacent region, such so that when it is removed, the majority of the media device remains on the media device, which is protected by the body section 410. Therefore, an advantage to the present protective case is its suitability for daily use, particularly with a detachable lens section 420 that comprises a lens window 50 (not illustrated in this embodiment), that does not protrude from the case, for ease of use.

The body section 410 and detachable lens sections 420 maybe made from any type of material that is suitable for a media case, including any or all of the materials described above with regard to the housing element 100 or the protective element 200. That is, the present protective case 400 may be made from the same materials and construction as the protective element 200 discussed above, but it is not limited to those materials or that particular construction.

To assemble the case on the media device, the body section 410 and lens section 420 are interconnected at edges 410a, 420a, and the media device is inserted into the case, such that the built-in camera lens is aligned with the lens window (not illustrated). Alternatively, the body section may be disposed first on the media device, followed by the lens section 420, which then can be joined to the body section 410 at edges 410a, 420a. When a user wants to take a video or photograph using an enhanced lens, the lens section 420 is removed and/or replaced with an alternative lens section 420. Therefore, it is not necessary to completely expose the media device, which therefore remains protected during the lens exchange, unlike other lens enhancement kits.

FIG. 14 shows another embodiment of a protective case 400′ for a media device in which the detachable lens section 420 comprises a relatively smaller region of the case than in the previous embodiment. In the present embodiment, the detachable lens section 420 does not form part of the case sidewall, as in the previous embodiment, thereby further improving the protective aspects of the case during the lens interchange.

Either or both of the foregoing cases 400, 400′ can be used with one or more one or more interchangeable and detachable lens sections 420, each with a different enhancement lens 80.

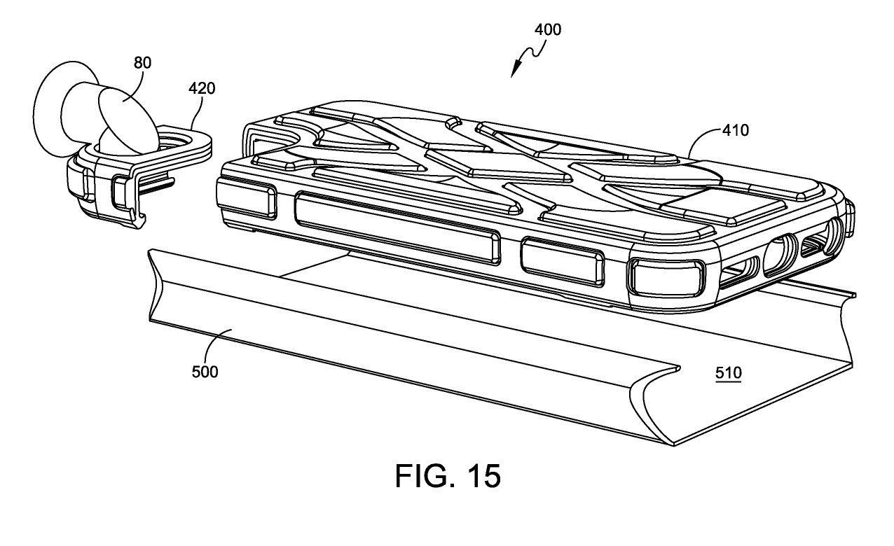

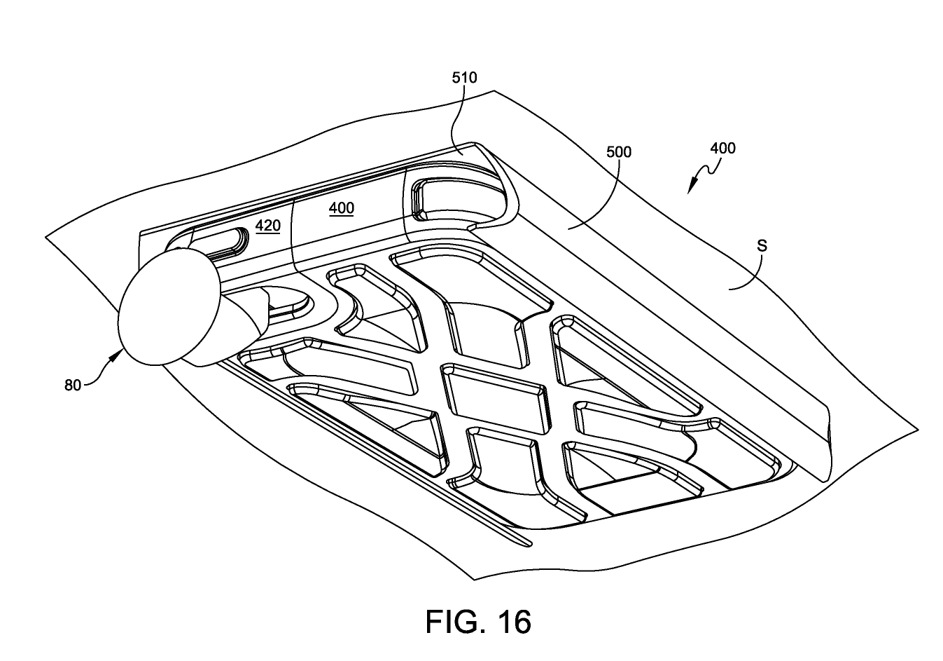

Another aspect of the present disclosure is the combination or integration of one or more securing structures for securing the housing systems and/or protective cases to one of a variety of separate mounting structures. FIG. 15 shows a sled 500 that can be mounted to a surface, in which the cases 400, 410 can be disposed such that the screen (not illustrated) of a media device, such as media device 300, is disposed adjacent to interior surface 510 of the sled. Therefore, the screen is protected by the sled, and the media device is protected by the case 400, 410. This type of arrangement provides a very low profile protective system for still and video photography, particularly action photography. For example, the sled can secured to a helmet, car, bicycle, the underside of a longboard, to the upper side of snowboard or surfboard, and the like, and to various other items. FIG. 16 shows the sled 500 mounted to the underside of surface S, such that the media screen faces and is protected by the interior surface 510 of the sled, while the opposite surface of the media device is protected by the case.

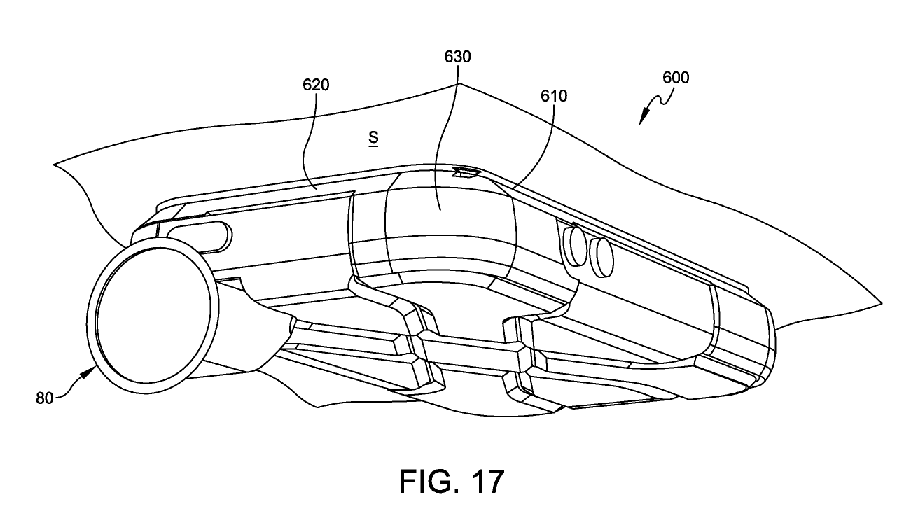

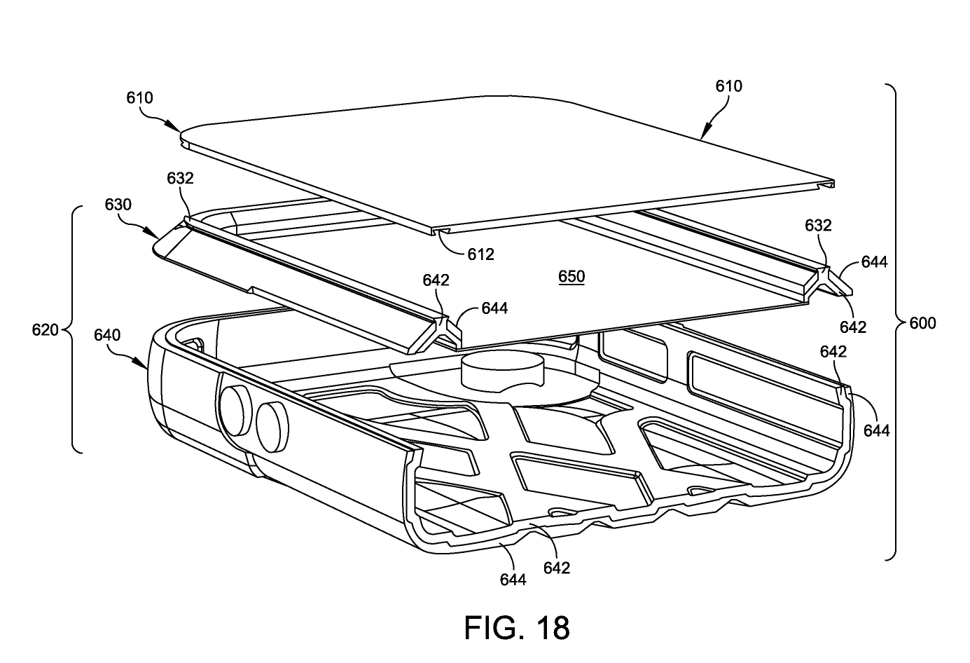

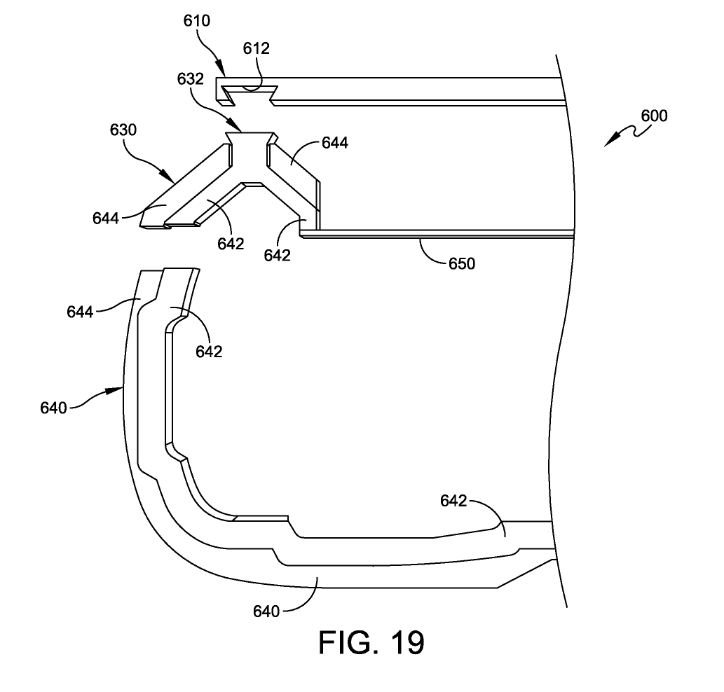

FIGS. 17-19 show another embodiment of a protective system 600 that comprises an integrated mounting system. As shown, system 600 comprises a sled 610 and a housing element 620.

Housing element 620 comprises a base section 640 and a cover section 630 that corresponds in shape and size to the base section 640. Base section 640 and a cover section 630 both comprise inner section 642 and an optional section 644 that can be made from any of the materials discussed above with regard to the housing and/or protective elements. In the present embodiment, the inner section 642 comprises a rigid material, such as polycarbonate, and the outer section 644 comprises a relatively softer material, such as a TPU.

Cover section 630 comprises a screen section 650 d, which may be made from the same material as the inner section, or may be a touchscreen membrane, interactive film, interactive glass (e.g., Xylo glass), and the like. Cover section 630 comprises opposing longitudinal rails 632 that engage channels on the sled 610.

Sled 610 has a rectangular shape corresponding to the shape of the housing element 620 and comprises two longitudinal channels 612 spaced part from the edges, for receiving corresponding rails 632 on the housing element 620. Sled 610 comprises a material with sufficient rigidity to be mounted to a surface S, and can be made from any of the materials discussed above with regard to the housing and/or protective elements.

In the present embodiment, the housing element 620 is sized and dimensioned to accommodate receiving a protective element therein, such as those described above, and functions in a similar manner to those described above. The base section and cover sections are closed using any of the fastening mechanisms described above in connection with previous embodiments.

Optionally, in any of the foregoing embodiments, the housing element 10 or portions thereof can comprise impact-absorbing regions (not illustrated) disposed on the outer surface to further improve the impact absorbing capabilities of the systems 100, 500. Thus, the housing element 10 can provide overall protection, and the external impact-absorbing regions can provide additional targeted protection to more vulnerable areas, such as edges and corners. The impact absorbing regions can comprise a variety of materials, including those described above with respect to the protective element 200.

Unless defined otherwise, technical and scientific terms used herein have the same meaning as is commonly understood by one of skill in the art to which this disclosure belongs.

It is noted that some embodiments described herein have used the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

Likewise, as used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Finally, as used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

It should be noted that the terms “first,” “second,” and the like herein do not denote any order or importance, but rather are used to distinguish one element from another, and the terms “a” and “an” herein do not denote a limitation of quantity, but rather denote the presence of at least one of the referenced items. Similarly, it is noted that the terms “bottom” and “top” are used herein, unless otherwise noted, merely for convenience of description, and are not limited to any one position or spatial orientation. In addition, the modifier “about” used in connection with a quantity is inclusive of the stated value and has the meaning dictated by the context (e.g., includes the degree of error associated with measurement of the particular quantity). The notation “+/−10% means that the indicated measurement may be from an amount that is minus 10% to an amount that is plus 10% of the stated value.

While the disclosure has been described with reference to an exemplary embodiment, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

What is claimed is:

1. A protective case for a media device with a built-in camera lens, comprising:
a protective element comprising a base and a sidewall extending upwardly from the base to define an enclosure adapted to receive the media device;
a housing element comprising a base and a sidewall extending upwardly from the base to define an enclosure adapted to receive the protective element, and a cover removably connected to the base;
a lens window disposed in the base;
wherein, when the media device is disposed in the protective case, the built-in camera lens is coaxially aligned with the lens window, and the protective element is sufficiently compressed against the interior of the enclosure to maintain the built-in lens in coaxial alignment with the lens window.

2. The protective case of claim 1, wherein the protective element comprises a resilient material.

3. The protective case of claim 1, wherein the resilient material is a rate dependent foam.

4. The protective case of claim 1, further comprising a detachable enhancement lens interconnected to the base and in coaxial alignment with the lens window.

5. The protective case of claim 4, wherein the enhancement lens redirects an image received through the lens to the media device.
